(19) United States
(12) Patent Application Publication
(10) Pub. No.: US 2020/0095117 A1
(43) Pub. Date: Mar. 26, 2020

(54) MEMS DEVICE

(71) Applicant: Seoul National University R&DB Foundation, Seoul (KR)

(72) Inventor: Suhwan KIM, Seoul (KR)

(73) Assignee: Seoul National University R&DB Foundation, Seoul (KR)

(21) Appl. No.: 16/698,766

(22) Filed: Nov. 27, 2019

Related U.S. Application Data
(63) Continuation of application No. PCT/KR2018/004619, filed on Apr. 20, 2018.

(30) Foreign Application Priority Data
May 30, 2017 (KR) 10-2017-0066667

(51) Int. Cl. B81B 7/00

(52) U.S. Cl. CPC B81B 7/0061; B81B 2207/012; B81B 2203/0127

(57) ABSTRACT

A microelectromechanical sensors (MEMS) device includes a MEMS transducer attached on a substrate; a semiconductor chip attached on the substrate and electrically connected to the MEMS transducer; and a case attached on the substrate so that the MEMS transducer and the semiconductor chip be covered, wherein the substrate includes a first passage formed below the MEMS transducer, wherein the case includes a second passage, and wherein the MEMS transducer includes a diaphragm having a third passage formed therein.

### CROSS-REFERENCE TO RELATED APPLICATIONS

This application is a continuation of and claims priority to PCT application No. PCT/KR2018/004619, filed on Apr. 20, 2018, which claims priority to Korean Patent Application No. 10-2017-0066667, filed on May 30, 2017, which is incorporated herein by reference in its entirety.

### BACKGROUND

### 1. Technical Field

Various embodiments generally relate to a microelectromechanical systems (MEMS) device and more particularly to a MEMS device for generating an electrical signal corresponding to fluid mixed inside of a transducer where the fluid flows through passages formed above and below the transducer.

### 2. Related Art

FIG. 1 shows a cross-sectional view of a MEMS device according to a conventional art.

The conventional MEMS device includes a substrate 30, a transducer 10 attached on the substrate 30, a semiconductor chip 20, and a case 40.

The transducer 10 and the semiconductor chip 20 is electrically connected via a conductive wire 21 and the semiconductor chip 20 and the substrate 30 is electrically connected via a conductive wire 22.

The transducer 10 includes a diaphragm 11 and an inner space 12.

In the conventional MEMS device, a passage 41 is formed on the case 40.

In the conventional MEMS device, air introduced from the passage 41 formed on the case 40 of the transducer causes vibration to the diaphragm 11 of the transducer 10 and makes the movement of the diaphragm 11 be converted into an electrical signal.

The electrical signal is processed in the semiconductor chip 20 and output to the outside.

In addition, in the conventional MEMS device, the diaphragm 11 is in a blocked state, and air introduced from the passage 41 does not pass through the diaphragm 11.

The conventional MEMS device generates an electrical signal by vibrating the diaphragm 11 of the transducer 10 according to pressure of the introduced air, thereby limiting the generation of the electrical signal corresponding to the mixed state of the air introduced from a plurality of directions.

### SUMMARY

In accordance with the present teachings, an microelectromechanical systems (MEMS) device may include a MEMS transducer attached on a substrate; a semiconductor chip attached on the substrate and electrically connected to the MEMS transducer; and a case attached on the substrate so that the MEMS transducer and the semiconductor chip be covered, wherein the substrate includes a first passage formed below the MEMS transducer, wherein the case includes a second passage, and wherein the MEMS transducer includes a diaphragm having a third passage formed therein.

### BRIEF DESCRIPTION OF THE DRAWINGS

The accompanying figures, where like reference numerals refer to identical or functionally similar elements throughout the separate views, together with the detailed description below, are incorporated in and form part of the specification, and serve to further illustrate embodiments of concepts that include the claimed novelty, and explain various principles and advantages of those embodiments.

FIG. 1 shows a cross-sectional view of a MEMS device according to a conventional art

FIGS. 2 to 7 show cross-sectional views of MEMS devices according to various embodiments of the present disclosure.

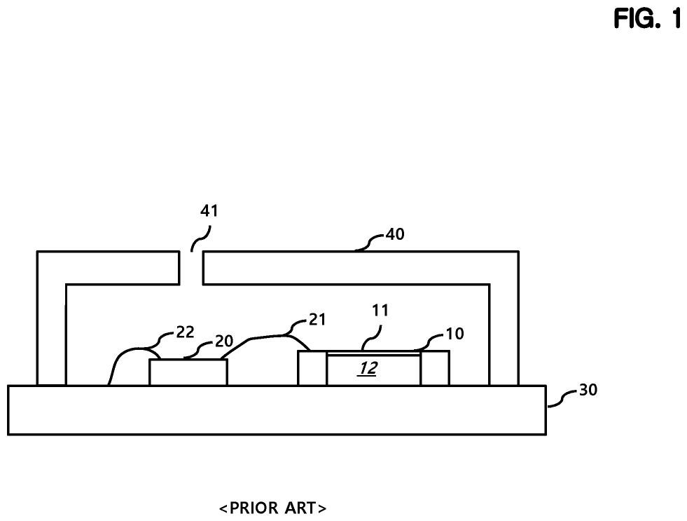

### DETAILED DESCRIPTION

The following detailed description references the accompanying figures in describing embodiments consistent with this disclosure. The examples of the embodiments are provided for illustrative purposes and are not exhaustive. Additional embodiments not explicitly illustrated or described are possible. Further, modifications can be made to presented embodiments within the scope of the present teachings. The detailed description is not meant to limit this disclosure. Rather, the scope of the present disclosure is defined only in accordance with the presented claims and equivalents thereof.

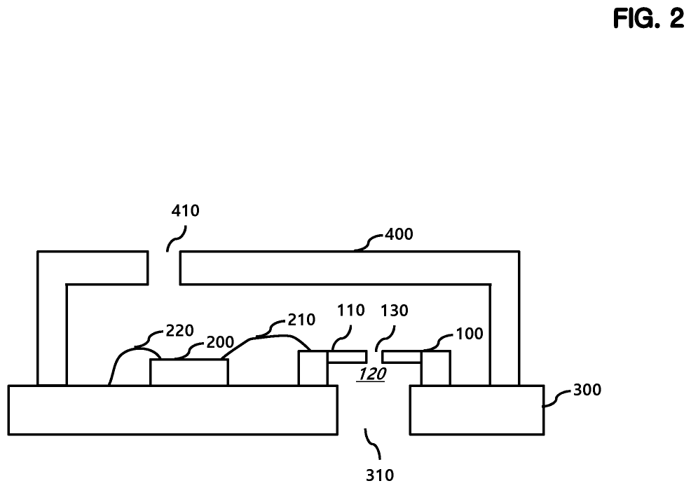

FIG. 2 show a cross-sectional view of a MEMS device according to an embodiment of the present disclosure.

The MEMS device according to an embodiment of the present disclosure includes a MEMS transducer 100, a semiconductor chip 200, a substrate 300, and a case 400.

The MEMS transducer 100 and the semiconductor chip 200 are attached on the substrate 300.

In the embodiment, the MEMS transducer 100 and the semiconductor chip 200 are electrically connected to each other via a conductive wire 210 and the semiconductor chip 200 and the substrate 300 are electrically connected to each other via a conductive wire 220.

In the present disclosure, a first passage 310 is formed at the substrate 300 below the MEMS transducer 100, and a second passage 410 is formed at the case 400 above the MEMS transducer 100.

The first passage 310 and the second passage 410 need not be symmetrically positioned with respect to the MEMS transducer 100, and the second passage 410 may be formed at an arbitrary position of the case 400.

The MEMS transducer 100 comprises a diaphragm 110 where a third passage 130 is formed.

The diaphragm 110 may comprise a piezoelectric material.

In this case, the diaphragm 110 may generate an electric signal according to the degree of bending, which may be transmitted to the semiconductor chip 200 via the conductive wire 210 and may be processed at the semiconductor chip 200.

The shape or number holes in the third passage 130 formed in the diaphragm 110 may be variously changed according to the embodiment.

For example, the third passage 130 may have one or more holes each have various shapes such as a circle, a rectangle, a triangle, and a cross shape on a plane.

The first passage 310, the second passage 410, and the third passage 130 may function as passages through which fluid such as air flows.

For this purpose, the first passage 310, the second passage 410, and the third passage 130 are preferably large enough to allow fluid to pass therethrough.

Fluid introduced from the first passage 310 and the second passage 410 may be mixed in the inner space 120 of the transducer 100 including the third passage 130.

Accordingly, the transducer 110 generates an electrical signal corresponding to the mixed state of the fluid introduced from the first passage 310 and the second passage 410.

Conventionally, in order to generate an electric signal corresponding to a mixed state of all fluids flowing from a plurality of directions, a device for mixing all fluids coming from a plurality of directions apart from the MEMS device may be additionally used.

In contrast, in the present disclosure, fluids introduced from the first passage 310 and the second passage 410 are mixed in the inner space 120 of the MEMS transducer 100 including the third passage 130. Accordingly, the electrical signal may be generated in response to the mixed state of the fluids introduced from the plurality of directions using one MEMS device.

In the present disclosure, the MEMS transducer 100 may generate an electrical signal corresponding to the flow of the fluid passing through the first passage 310, the second passage 410, and the third passage 130.

For example, when there is a constant flow of fluid passing through the first passage 310, the third passage 130, and the second passage 410, an electrical signal corresponding to the velocity, pressure, or the like of the fluid may be generated.

In this case, the fluid may include a gas or a liquid.

The position and number of holes in the first passage 310, the second passage 410, and the third passage 130 are not limited to a specific one, and various design changes are possible within the scope of the invention.

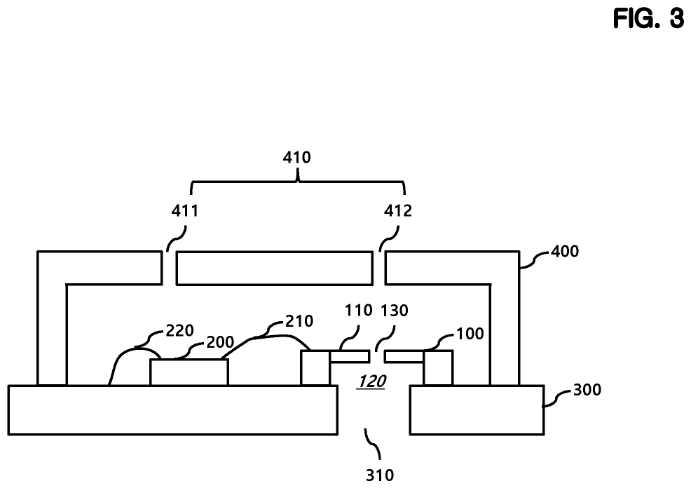

FIGS. 3 to 7 show various MEMS devices according to embodiments of the present disclosure.

For example, FIGS. 3 to 5 correspond to embodiments having a plurality of holes formed on the case 400.

Although the case 400 in the illustrated embodiments includes two holes, the number of holes is not limited thereto.

In FIG. 3, the second passage 410 formed in the case 400 includes a 21st hole 411 and a 22nd hole 412.

In an embodiment shown in FIG. 3, the 21st hole 411 and the 22nd hole 412 are located at a position spaced apart from each other and one of which is located at a position above the MEMS transducer 100.

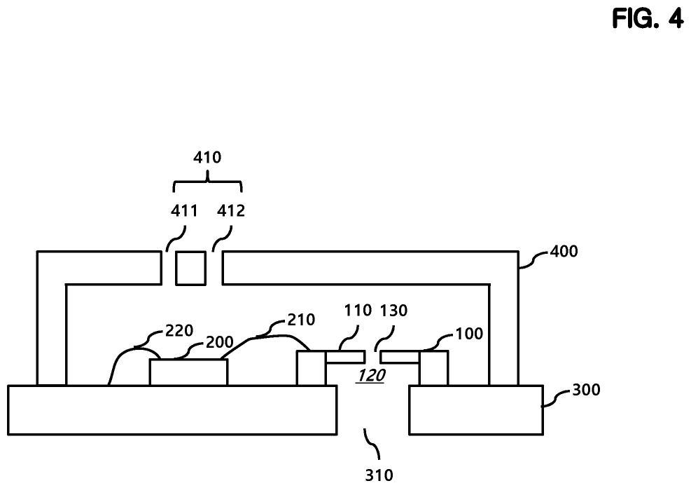

In an embodiment shown in FIG. 4, unlike the embodiment shown in FIG. 3, the 21st hole 411 and the 22nd hole 412 are formed at positions spaced apart from a position above the MEMS transducer 100.

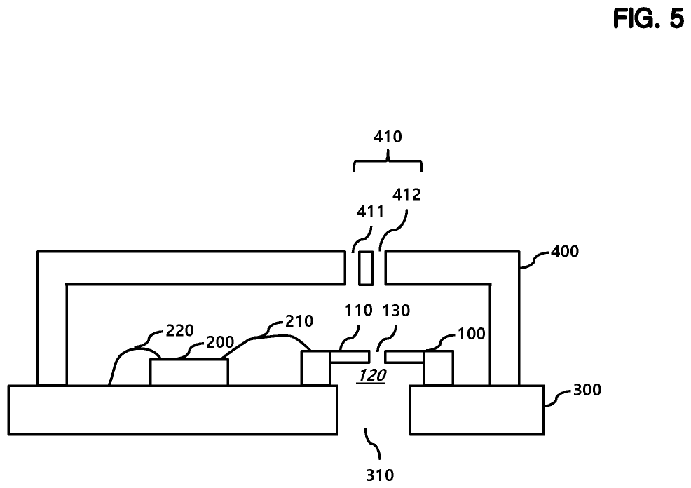

In an embodiment shown in FIG. 5, unlike the embodiment shown in FIG. 4, the 21st hold 411 and the 22nd hole 412 are formed above the MEMS transducer 100.

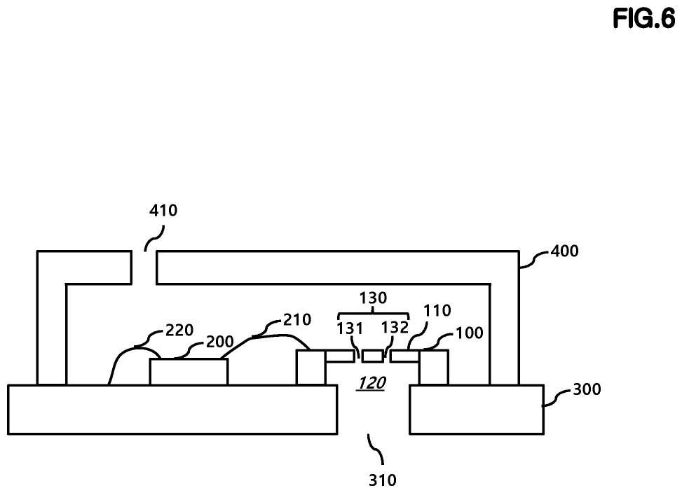

FIG. 6 illustrates an embodiment in which a plurality of holes are formed in the diaphragm 110.

In FIG. 6, the third passage 130 includes a 31st hole 131 and a 32nd hole 132.

FIG. 6 illustrates an embodiment where the number of holes in the third passage is two, but the number of holes is not limited thereto.

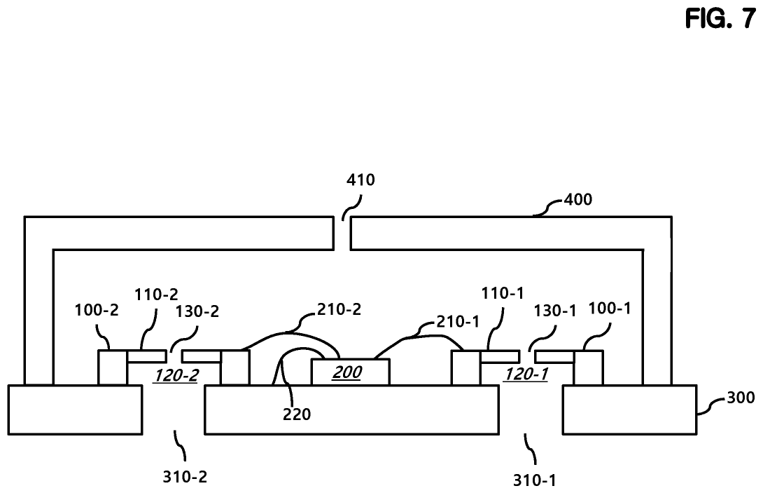

FIG. 7 illustrates a cross-sectional view of a MEMS device including a plurality of MEMS transducers.

In FIG. 7, the MEMS device includes two MEMS transducers 100-1 and 100-2, and their configurations are substantially the same.

That is, the MEMS transducer 100-1 include a diaphragm 110-1 having third passage 130-1 formed therein and the MEMS transducer 100-2 includes a diaphragm 110-2 having third passage 130-2 formed therein.

The third passage 130-1 may be referenced as a 31st passage and the third passage 130-2 may be referenced as a 32nd passage and each of them may include one or more holes.

Electrical signals generated by the bending of the diaphragms 110-1 and 110-2 are transmitted to the semiconductor chip 200 through the conductive wires 210-1 and 210-2.

The first passages 310-1 and 310-2 are formed in the substrate 300 to open an inner space 120-1 of the MEMS transducer 100-1 and an inner space 120-2 of the MEMS transducer 100-2 to the outside.

The first passage 310-1 may be referenced as a 11st passage and the first passage 310-2 may be referenced as a 12nd passage and each of them may include one or more holes.

Accordingly, fluids introduced through the first passage, the second passage, and the third passage may be mixed in the inner spaces 120-1 and 120-2 of the MEMS transducers 100-1 and 100-2.

In FIG. 7, a MEMS device including two MEMS transducers 100-1 and 100-2 and one semiconductor chip 200 is illustrated but number of MEMS transducers or semiconductor chips may vary depending on the embodiment.

Although various embodiments have been described for illustrative purposes, it will be apparent to those skilled in the art that various changes and modifications may be made to the described embodiments without departing from the spirit and scope of the disclosure as defined by the following claims.

What is claimed is:

1. A microelectromechanical sensors (MEMS) device comprising:
a MEMS transducer attached on a substrate;
a semiconductor chip attached on the substrate and electrically connected to the MEMS transducer; and
a case attached on the substrate so that the MEMS transducer and the semiconductor chip be covered,
wherein the substrate includes a first passage formed below the MEMS transducer,
wherein the case includes a second passage, and
wherein the MEMS transducer includes a diaphragm having a third passage formed therein.

2. The MEMS device of claim 1, wherein fluids passing the first passage and the second passage are mixed in an inner space of the MEMS transducer including the third passage.

3. The MEMS device of claim 1, wherein the MEMS transducer generates electrical signal corresponding to flow of fluids flowing through the first passage, the third passage, and the second passage.

4. The MEMS device of claim 1, wherein the second passage is formed at a position which is above the diaphragm or which is apart from a position above the diaphragm.

5. The MEMS device of claim 1, wherein at least one of the first passage and a second passage includes a plurality of holes.

6. The MEMS device of claim 5, wherein the second passage includes a plurality of holes which are formed above the diaphragm.

7. The MEMS device of claim 5, wherein the second passage includes a plurality of holes which are formed at positions which are spaced apart from a position above the diaphragm.

8. The MEMS device of claim 5, wherein the second passage includes a plurality of holes, at least one of which is formed at a position above the diaphragm and at least one of which is formed at a position which is spaced apart from a position above the diaphragm.

9. The MEMS device of claim 1, wherein the third passage includes one or more holes.

10. The MEMS device of claim 1, wherein the diaphragm comprises piezoelectric material.
